(19) United States
(12) Patent Application Publication
(10) Pub. No.: US 2010/0289118 A1
(43) Pub. Date: Nov. 18, 2010

(54) SEMICONDUCTOR DEVICE

(75) Inventor: Koichi Kokubun, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/715,594

(22) Filed: Mar. 2, 2010

(30) Foreign Application Priority Data
May 12, 2009 (JP) 2009-115239

(51) Int. Cl. H01L 23/528

(52) U.S. Cl. 257/531; 257/E23.151

(57) ABSTRACT

A semiconductor device has an inductor. The inductor has a first metal interconnection layer formed in the insulation film to extend in a first direction which is parallel to a substrate face of the semiconductor substrate, and connected electrically at a first end part thereof to the first terminal; a first via interconnection formed in the insulation film to extend in a second direction perpendicular to the substrate face, and connected at a top part thereof to a second end part of the first metal interconnection layer; and a second metal interconnection layer formed in the insulation film to extend in the first direction under the first metal interconnection layer, facing to the first metal interconnection layer, insulated from the first metal interconnection layer by the insulation film, connected at a first end part thereof to a bottom part of the first via interconnection, and connected electrically at a second end part thereof to the second terminal.

### CROSS-REFERENCE TO RELATED APPLICATION

This application is based upon and claims the benefit of priority from the prior Japanese Patent Application No.2009-115239, filed on May 12, 2009, the entire contents of which are incorporated herein by reference.

### BACKGROUND

A chip of CMOSLSI (Complementary Metal-Oxide Semiconductor Large-Scale Integrated circuit) includes mainly a logic part and an analog part. The size shrinking of the logic part has been promoted by advancement of the size shrinking technique made until now. In the analog part, however, it is difficult to shrink the area of especially an inductor which is a passive element.

In the SOC (System On Chip) technique using CMOS size shrinking, reduction of the area of the analog part poses a big problem from the viewpoint of the cost impact.

As a cause to make it impossible to shrink the area of the inductor as described above, a plane layout pattern can be mentioned. If the number of windings of the inductor is increased in order to, for example, increase a value of inductance formed two-dimensionally on a plane parallel to the substrate plane, then the area of the inductor increases depending upon the number of windings.

Some conventional semiconductor devices include an inductor having a three-dimensional structure (for example, see Japanese Patent Laid-Open No. 8-250332). If the number of windings is increased to increase inductance of the inductor, however, the area of the plane layout of the inductor increases. In the above-described conventional art, there is a problem that the chip area increases if it is attempted to increase the inductance.

### SUMMARY

According to one aspect of the present invention, there is provided: a semiconductor device comprising:

an insulation film formed over a semiconductor substrate; and

an inductor formed in the insulation film and connected between a first terminal and a second terminal,

wherein the inductor comprises:

a first metal interconnection layer formed in the insulation film to extend in a first direction which is parallel to a substrate face of the semiconductor substrate, and connected electrically at a first end part thereof to the first terminal;

a first via interconnection formed in the insulation film to extend in a second direction perpendicular to the substrate face, and connected at a top part thereof to a second end part of the first metal interconnection layer; and

a second metal interconnection layer formed in the insulation film to extend in the first direction under the first metal interconnection layer, facing to the first metal interconnection layer, insulated from the first metal interconnection layer by the insulation film, connected at a first end part thereof to a bottom part of the first via interconnection, and connected electrically at a second end part thereof to the second terminal.

### BRIEF DESCRIPTION OF THE DRAWINGS

FIG. 1 is a diagram showing an example of a configuration of a semiconductor device 100 according to a first embodiment which is an aspect of the present invention;

FIG. 2 is a top view showing a plane structure obtained by taking notice of an inductor 4 in the semiconductor device 100 shown in FIG. 1;

FIG. 3 is a sectional view showing a sectional structure of the inductor 4 obtained along an A-A′ line shown in FIG. 2;

FIGS. 4 to 6 are top views showing examples of a plane structure in the vicinity of an area 4z of the inductor 4 surrounded by a dashed line in FIGS. 2 and 3;

FIG. 7 is a top view showing an example of a plane structure in the case where the inductors 4 in the semiconductor device 100 shown in FIG. 1 are connected in series; and

FIG. 8 is a circuit diagram showing a circuit configuration of the inductors 4 connected in series shown in FIG. 7.

### DETAILED DESCRIPTION

Hereafter, embodiments of a semiconductor device according to the present invention will be described more specifically with reference to the drawings.

### First Embodiment

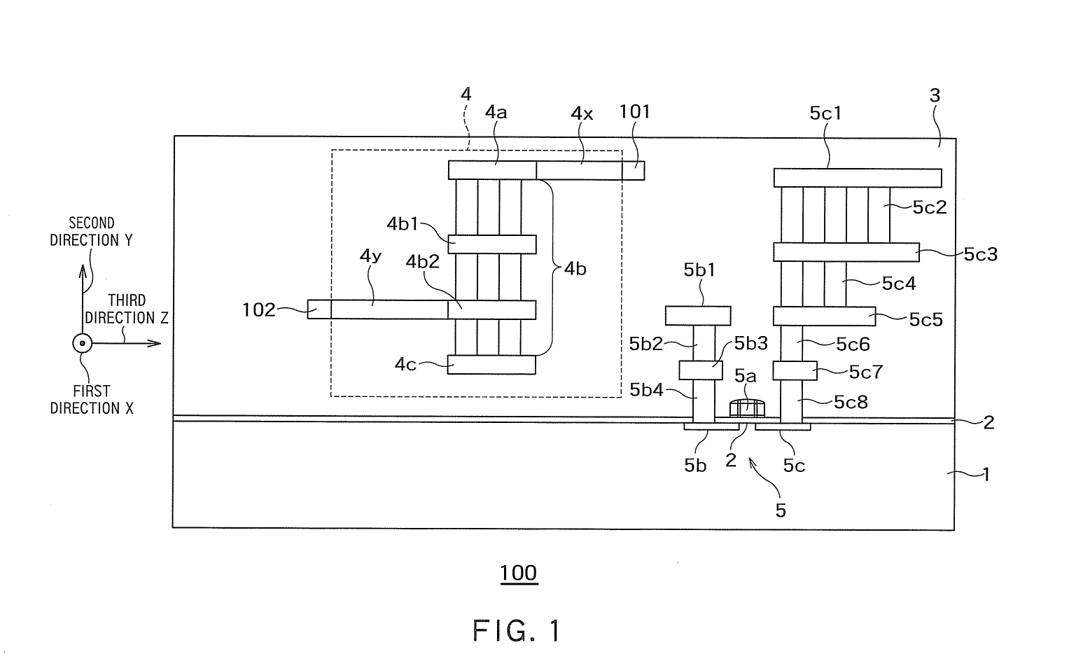

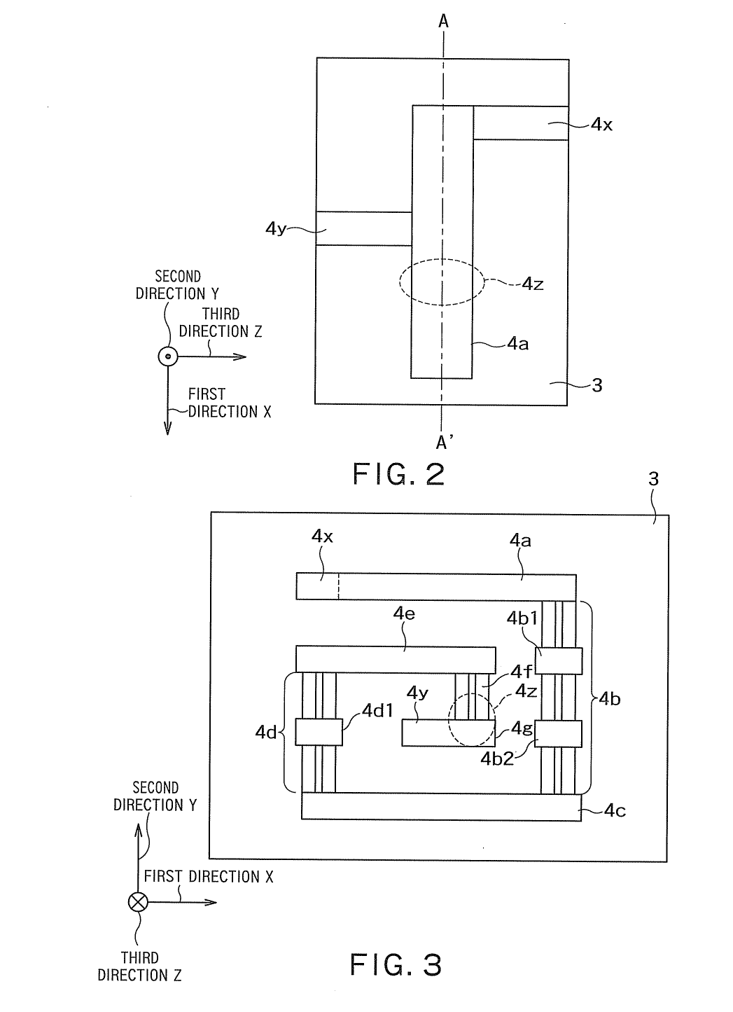

FIG. 1 is a diagram showing an example of a configuration of a semiconductor device 100 according to a first embodiment which is an aspect of the present invention. FIG. 2 is a top view showing a plane structure obtained by taking notice of an inductor 4 in the semiconductor device 100 shown in FIG. 1. FIG. 3 is a sectional view showing a sectional structure of the inductor 4 obtained along an A-A′ line shown in FIG. 2.

As shown in FIG. 1, the semiconductor device 100 includes a semiconductor substrate 1, a gate insulation film 2, an interlayer insulation film 3, an inductor 4, a MOS transistor 5, a first terminal 101, and a second terminal 102.

The semiconductor substrate 1 is formed of, for example, a semiconductor containing silicon or germanium as its principal component.

The gate insulation film 2 is an insulation film formed on the semiconductor substrate 1. The gate insulation film 2 functions as, for example, a gate insulation film for the MOS transistor 5.

The interlayer insulation film 3 is an insulation film formed over the semiconductor substrate 1 via the gate insulation film 2.

The inductor 4 is formed in the interlayer insulation film 3. The inductor 4 is connected between the first terminal 101 and the second terminal 102.

The MOS transistor 5 is formed on the semiconductor substrate 1. The MOS transistor 5 includes the gate insulation film 2 formed on the semiconductor substrate 1, a gate electrode 5a formed over the semiconductor substrate 1 via the gate insulation film 2, and source-drain regions 5b and 5c formed in the semiconductor substrate 1 to have the gate electrode 5a between.

In the interlayer insulation film 3, a metal interconnection layer 5b1 is electrically connected to the source-drain region 5b via a via interconnection 5b2, a metal interconnection layer 5b3, and a via interconnection 5b4.

In the interlayer insulation film 3, a metal interconnection layer 5c1 is electrically connected to the source-drain region Sc via a via interconnection 5c2, a metal interconnection layer 5c3, a via interconnection 5c4, a metal interconnection layer 5c5, a via interconnection 5c6, a metal interconnection layer 5c7, and a via interconnection 5c8.

Each of the first terminal 101 and the second terminal 102 is electrically connected to an internal circuit which is not illustrated or an external terminal which is not illustrated, via, for example, an interconnection layer which is not illustrated.

As shown in FIGS. 1 to 3, the inductor 4 includes a first metal interconnection layer 4a, a first via interconnection 4b, first relay interconnection layers 4b1 and 4b2, a second metal interconnection layer 4c, a second via interconnection 4d, a second relay interconnection layer 4d1, a third metal interconnection layer 4e, a third via interconnection 4f, a fourth metal interconnection layer 4g, a first pull-out interconnection layer 4x, and a second pull-out interconnection layer 4y. These interconnection layers and interconnections have conductivity.

The first metal interconnection layer 4a is formed in the interlayer insulation film 3 to extend in a first direction X which is parallel to a substrate face of the semiconductor substrate 1. The first metal interconnection layer 4a is electrically connected at its first end part to the first terminal 101 via the first pull-out interconnection layer 4x.

The first via interconnection 4b is formed in the interlayer insulation film 3 to extend in a second direction Y which is perpendicular to the substrate face. The first via interconnection 4b is connected at its top part to a second end part of the first metal interconnection layer 4a.

The second metal interconnection layer 4c is formed under the first metal interconnection layer 4a in the interlayer insulation film 3 to extend in the first direction X and be opposed to the first metal interconnection layer 4a. The second metal interconnection layer 4c is insulated from the first metal interconnection layer 4a by the interlayer insulation film 3. The second metal interconnection layer 4c has the same length as that of the first metal interconnection layer 4a. The second metal interconnection layer 4c is connected at its first end part to a bottom part of the first via interconnection 4b, and electrically connected at its second end part to the second terminal 102 via other metal interconnection layers and via interconnections.

The second via interconnection 4d is formed in the interlayer insulation film 3 to extend in the second direction Y, and connected at its bottom part to a second end part of the second metal interconnection layer 4c.

The third metal interconnection layer 4e is formed in the interlayer insulation film 3 to extend in the first direction X between the first metal interconnection layer 4a and the second metal interconnection layer 4c. The third metal interconnection layer 4e is insulated from the first metal interconnection layer 4a and the second metal interconnection layer 4c by the interlayer insulation film 3. The third metal interconnection layer 4e has a length which is shorter than that of the second metal interconnection layer 4c. The third metal interconnection layer 4e is connected at its first end part to a top part of the second via interconnection 4d, and electrically connected at its second end part to the second terminal 102 via a different metal interconnection layer and a via interconnection.

The third via interconnection 4f is formed in the interlayer insulation film 3 to extend in the second direction Y, and connected at its top part to the second end part of the third metal interconnection layer 4e.

The fourth metal interconnection layer 4g is formed in the interlayer insulation film 3 to extend in the first direction X between the second metal interconnection layer 4c and the third metal interconnection layer 4e. The fourth metal interconnection layer 4g is insulated from the first metal interconnection layer 4a, the second metal interconnection layer 4c, and the third metal interconnection layer 4e by the interlayer insulation film 3. The fourth metal interconnection layer 4g has a length which is shorter than that of the third metal interconnection layer 4e. The fourth metal interconnection layer 4g is connected at its first end part to a bottom part of the third via interconnection 4f, and electrically connected at its second end part to the second terminal 102 via the second pull-out interconnection layer 4y.

The first pull-out interconnection layer 4x is electrically connected to the first terminal 101, and formed to extend in a third direction Z which is parallel to the substrate face and which is perpendicular to the first direction X. As already described, the first end of the first metal interconnection layer 4a is electrically connected to the first terminal 101 via the first pull-out interconnection layer 4x.

The second pull-out interconnection layer 4y is electrically connected to the second terminal 102, and formed to extend in the third direction Z. As already described, the second end part of the fourth metal interconnection layer 4g (the second metal interconnection layer 4c and the third metal interconnection layer 4e) is electrically connected to the second terminal 102 via the second pull-out interconnection layer 4y.

The first relay interconnection layers 4b1 and 4b2 are formed to relay the first via interconnection 4b between the second end part of the first metal interconnection layer 4a and the first end part of the second metal interconnection layer 4c in the interlayer insulation film 3.

The first relay interconnection layers 4b1 and 4b2 may be omitted. In that case, the second end part of the first metal interconnection layer 4a and the first end part of the second metal interconnection layer 4c are electrically connected to each other only by the first via interconnection 4b.

The second relay interconnection layer 4d1 is formed to relay the second via interconnection 4d between the second end part of the second metal interconnection layer 4c and the first end part of the third metal interconnection layer 4e in the interlayer insulation film 3.

The second relay interconnection layer 4d1 may be omitted. In that case, the second end part of the second metal interconnection layer 4c and the first end part of the third metal interconnection layer 4e are electrically connected to each other only by the second via interconnection 4d.

The first metal interconnection layer 4a, the second metal interconnection layer 4c, the third metal interconnection layer 4e, and the fourth metal interconnection layer 4g have the same width.

The first relay interconnection layer 4b1 and the third metal interconnection layer 4e are formed at the same height from the substrate face of the semiconductor substrate 1.

The first relay interconnection layer 4b2, the second relay interconnection layer 4d1, and the fourth metal interconnection layer 4g are formed at the same height from the substrate face of the semiconductor substrate 1.

As shown in FIGS. 2 and 3, the first metal interconnection layer 4a, the first via interconnection 4b, the second metal interconnection layer 4c, the second via interconnection 4d, and the third metal interconnection layer 4e are formed on one face perpendicular to the substrate face of the semiconductor substrate 1.

As shown in FIGS. 1 to 3, the inductor 4 has a spiral structure including the metal interconnection layers and the via interconnection. The area of the inductor 4 on a plane which is parallel to the substrate face of the inductor 4 is only the area of the first metal interconnection layer 4a, and the first and second pull-out interconnection layers 4x and 4y on the plane which is parallel to the substrate face.

In other words, the value of the inductance of the inductor 4 having the above-described configuration can be increased without increasing the area of the plane which is parallel to the substrate face. As a result, the area of the chip can be reduced.

The spiral structure of the inductor 4 can be basically formed by using the existing BEOL (Back-End-of-Line) process of the CMOS.

As occasion demands, the number of windings of the inductor 4 can be increased by increasing the number of layers of the metal interconnection layers of the inductor 4.

By the way, the inductance of the inductor 4 can also be increased by setting the magnetic permeability of the interlayer insulation film 3 equal to a higher value.

In this way, in the inductor 4 having the above-described configuration, the area of the plane layout can be reduced as compared with the conventional inductance having plane spiral.

In addition, in the inductor 4 having the configuration, coupling noise to the semiconductor substrate 1 can be reduced, because the area of the inductor 4 on the plane parallel to the substrate face can be reduced as compared with the conventional inductor.

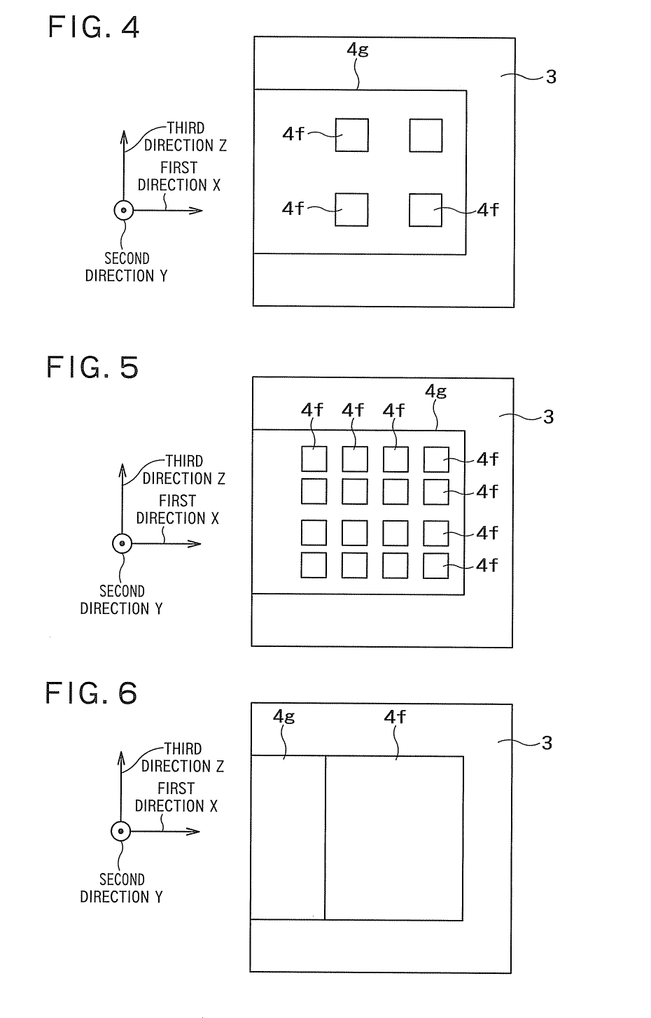

FIGS. 4 to 6 are top views showing examples of a plane structure in the vicinity of an area 4z of the inductor 4 surrounded by a dashed line in FIGS. 2 and 3.

As shown in FIG. 4, a plurality of (here, four) third via interconnections 4f are formed. As a result, the interconnection resistance of the inductor 4 is decreased as compared with the case where one via interconnection having the same cross-sectional area is formed.

As shown in FIG. 5, as many third via interconnections 4f as possible may be formed in conformity with the width of the fourth metal interconnection layer 4g in order to further decrease the interconnection resistance of the inductor 4.

As shown in FIG. 6, the width of the third via interconnection 4f may be set equal to that of the fourth metal interconnection layer 4g. As a result, the area of the connection between the metal interconnection layer and the via interconnection can be maximized. In other words, the resistance of connection between the metal interconnection layer and the via interconnection can be further decreased.

The relation between the third metal interconnection layer 4e and the third via interconnection 4f also becomes similar to that shown in FIGS. 4 to 6.

As for the first and second via interconnections 4b and 4d as well, a plurality of via interconnections may be formed in the same way as the case shown in FIGS. 4 and 5 in order to decrease the interconnection resistance of the inductor 4. In the same way as the case shown in FIG. 6, the width of the first and second via interconnections 4b and 4d may be set equal to that of the connected metal interconnection layer.

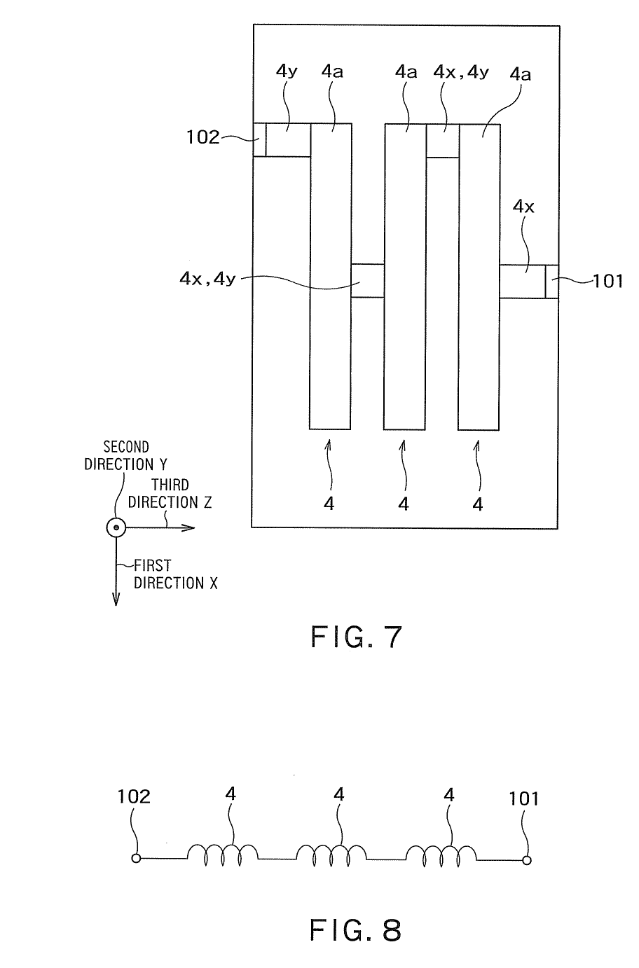

FIG. 7 is a top view showing an example of a plane structure in the case where the inductors 4 in the semiconductor device 100 shown in FIG. 1 are connected in series. FIG. 8 is a circuit diagram showing a circuit configuration of the inductors 4 connected in series shown in FIG. 7.

As shown in FIGS. 7 and 8, the semiconductor device 100 may include a plurality of inductors 4 connected in series between the first terminal 101 and the second terminal 102. If greater inductance is needed, therefore, then the needed inductance can be obtained while attempting to reduce the area of the chip, by increasing the number of the inductors 4 connected in series.

According to the semiconductor device in the present embodiment, the area of the chip can be reduced as heretofore described.

From the above description, those skilled in the art will appreciate additional advantages and be able to devise various modifications. Therefore, the aspects of the present invention are not limited to the embodiments specifically described above. Various additions, modifications, and partial omissions are possible without departing from the concept and spirit of the present invention, which are derived from the contents defined by the claims and equivalents thereto.

What is claimed is:

1. A semiconductor device comprising:
an insulation film formed over a semiconductor substrate; and
an inductor formed in the insulation film and connected between a first terminal and a second terminal,
wherein the inductor comprises:
a first metal interconnection layer formed in the insulation film to extend in a first direction which is parallel to a substrate face of the semiconductor substrate, and connected electrically at a first end part thereof to the first terminal;
a first via interconnection formed in the insulation film to extend in a second direction perpendicular to the substrate face, and connected at a top part thereof to a second end part of the first metal interconnection layer; and
a second metal interconnection layer formed in the insulation film to extend in the first direction under the first metal interconnection layer, facing to the first metal interconnection layer, insulated from the first metal interconnection layer by the insulation film, connected at a first end part thereof to a bottom part of the first via interconnection, and connected electrically at a second end part thereof to the second terminal.

2. The device of claim 1, wherein the inductor further comprises:
a second via interconnection formed in the insulation film to extend in the second direction, and connected at a bottom part thereof to the second end part of the second metal interconnection layer; and
a third metal interconnection layer formed in the insulation film to extend in the first direction between the first metal interconnection layer and the second metal interconnection layer, insulated from the first metal interconnection layer and the second metal interconnection layer by the insulation film, having a length which is shorter than that of the second metal interconnection layer, connected at a first end part thereof to a top part of the second via interconnection, and connected electrically at a second end part thereof to the second terminal.

3. The device of claim 1, wherein the inductor further comprises:
a first pull-out interconnection layer formed in the insulation film to extend in a third direction which is parallel to the substrate face and which is perpendicular to the first direction, and electrically connected to the first terminal; and
a second pull-out interconnection layer formed in the insulation film to extend in the third direction, and electrically connected to the second terminal,
the first end of the first metal interconnection layer is electrically connected to the first terminal via the first pull-out interconnection layer, and
the second end part of the second metal interconnection layer is electrically connected to the second terminal via the second pull-out interconnection layer.

4. The device of claim 2, wherein the inductor further comprises:
a first pull-out interconnection layer formed in the insulation film to extend in a third direction which is parallel to the substrate face and which is perpendicular to the first direction, and electrically connected to the first terminal; and
a second pull-out interconnection layer formed in the insulation film to extend in the third direction, and electrically connected to the second terminal,
the first end of the first metal interconnection layer is electrically connected to the first terminal via the first pull-out interconnection layer, and
the second end part of the second metal interconnection layer is electrically connected to the second terminal via the second pull-out interconnection layer.

5. The device of claim 1, wherein the inductor further comprises:
a first relay interconnection layer formed to relay the first via interconnection between the second end part of the first metal interconnection layer and the first end part of the second metal interconnection layer in the insulation film.

6. The device of claim 2, wherein the inductor further comprises:
a first relay interconnection layer formed to relay the first via interconnection between the second end part of the first metal interconnection layer and the first end part of the second metal interconnection layer in the interlayer insulation film.

7. The device of claim 3, wherein the inductor further comprises:
a first relay interconnection layer formed to relay the first via interconnection between the second end part of the first metal interconnection layer and the first end part of the second metal interconnection layer in the insulation film.

8. The device of claim 1, comprising a plurality of the inductors connected in series.

9. The device of claim 2, comprising a plurality of the inductors connected in series.

10. The device of claim 1, wherein the first metal interconnection layer, the first via interconnection, and the second metal interconnection layer are formed on one face perpendicular to the substrate face of the semiconductor substrate.

11. The device of claim 2, wherein the first metal interconnection layer, the first via interconnection, the second metal interconnection layer, the second via interconnection, and the third metal interconnection layer are formed on one face perpendicular to the substrate face of the semiconductor substrate.

12. The device of claim 1, wherein the first metal interconnection layer and the second metal interconnection layer have a substantially same width.

13. The device of claim 1, wherein the first relay interconnection layer and the third metal interconnection layer are formed at a substantially same height from the substrate face of the semiconductor substrate.

14. The device of claim 1, wherein the inductor further comprises:
a second relay interconnection layer formed to relay the second via interconnection between the second end part of the second metal interconnection layer and the first end part of the third metal interconnection layer in the insulation film.

15. The device of claim 1, wherein a plurality of the first via interconnections are formed.

16. The device of claim 2, wherein a plurality of the second via interconnections are formed.

17. The device of claim 1, wherein
a width of the first via interconnection is set substantially equal to that of the first metal interconnection layer and the second metal interconnection layer.

18. The device of claim 1, wherein
a width of the second via interconnection is set substantially equal to that of the second metal interconnection layer and the third metal interconnection layer.

19. The device of claim 1, wherein a length of the second metal interconnection layer is substantially equal to a length of the first metal interconnection layer.
